(19) United States
(12) Patent Application Publication
(10) Pub. No.: US 2004/0098644 A1
(43) Pub. Date: May 20, 2004

(54) System and method for generating a graphical representation of fault data of a memory device under test

(76) Inventors: John Wuu, Ft. Collins, CO (US); Douglas John Cutter, Ft. Collins, CO (US)

Correspondence Address: HEWLETT-PACKARD COMPANY, Intellectual Property Administration, P.O. Box 272400, Fort Collins, CO, 80527-2400, US

(21) Appl. No.: 10/298,729

(22) Filed: Nov. 18, 2002

(51) Int. Cl. G11C 29/00

(52) U.S. Cl. 714/723

(57) ABSTRACT

A system and method for generating a graphical representation of fault data of a memory device under test is disclosed. A location-specific count of failing locations of the memory device is maintained as varying parameters are applied to the memory device. A symbol is assigned to each failing location based on its location-specific count. The symbols are plotted in an array representative of the memory device under test.

### BACKGROUND OF THE INVENTION

1. Technical Field of the Invention

The present invention generally relates to parametric verification of electronic circuitry. More particularly, and not by way of any limitation, the present invention is directed to a system and method for generating a graphical representation of fault data of a memory device under test.

2. Description of Related Art

Without limiting the scope of the invention, the Description of Related Art is described in connection with memory devices, as an example. The electrical verification of memory devices under test (MDUTs) is concerned with ensuring quality memory device design by seeking to find and correct design faults. More specifically, the electrical verification of the MDUTs includes extensive testing to diagnose failures in as many of the MDUTs' logic states, signal paths, and state transitions as possible prior to the release and shipment of the devices.

In general, an electrical failure can be described as the malfunction of an MDUT under certain but not all operating parameters. For example, typical electrical failures include latch setup or hold time violations, noise issues, charge-sharing issues, leakage issues, and cross talk. The task of identifying these electrical failures and others involves a number of operations. Initially, test vectors are designed, generated, and executed on the MDUT under a variety of operating parameters. The data collected from the execution of these test vectors is then displayed graphically in what are commonly known as bitmap plots which reveal whether the MDUT passed or failed as a function of the various combinations of electrical parameters applied to it. Next, the bitmap plots are meticulously examined for anomalies. Thereafter, the anomalies are checked for repeatability. If the anomaly repeats reliably, the failure signature of the anomaly is analyzed to determine the root cause of the failure so that the failure may be repaired.

Accordingly, the process of identifying anomalies in bitmap plots is of particular importance. To effectively identify anomalies in bitmap plots, the MDUT must be exercised using a large number of electrical parameters which produce a corresponding large number of bitmap plots. Examining the large number of bitmap plots produced by a fully exercised MDUT, however, has proved to be difficult. FIG. 1 (Prior Art) depicts six bitmap plots 102A-102F illustrating a memory array portion of an MDUT having twelve memory locations. Bitmap plots 102A-102F reveal whether these memory locations of the MDUT passed or failed as a function of an electrical parameter having values P₁-P₆, respectively. In order to observe anomalies and any patterns therein, all six of the bitmap plots must be examined in detail. For example, a pattern in the failure behavior of three bit locations, B₁-B₃, is illustrated herein. Memory location B₁ fails at parameter value P₂ and memory locations B₂ and B₃ start failing at parametric values P₃ and P₄, respectively. As exemplified, accordingly, all six bitmap plots need to be examined in order to discern the functional parametric variability.

By way of extrapolation, it should be appreciated that one is required to examine a large number of “bitmaps” to observe any failure patterns in a typical memory device, especially where the applied parameter is varied over a substantial range in numerous increments. However, doing so is very inefficient, and as failures can often be large in number and scattered in different regions, keeping track of different failures across several bitmaps becomes very difficult.

### SUMMARY OF THE INVENTION

A system and method for generating a graphical representation of fault data of a memory device under test is disclosed. A location-specific count of failing locations of the memory device is maintained as varying parameters are applied to the memory device. A symbol is assigned to each failing location based on its location-specific count. The symbols are plotted in an array representative of the memory device under test.

### BRIEF DESCRIPTION OF THE DRAWINGS

A more complete understanding of the present invention may be had by reference to the following Detailed Description when taken in conjunction with the accompanying drawings wherein:

FIG. 1 (Prior Art) depicts six bitmap plots illustrating a memory array portion of a memory device under test (MDUT);

FIG. 2 depicts a functional block diagram of one embodiment of a system for generating a graphical representation of fault data of an MDUT in accordance with the teachings of the present invention;

FIG. 3 depicts a flow chart of one embodiment of a method for generating a graphical representation of fault data of an MDUT;

FIG. 4 depicts a graphical representation of failure data of the memory array portion shown in FIG. 1; and

FIG. 5 depicts a flow chart representing a particular embodiment of the method of FIG. 3 for generating the graphical representation of fault data of an MDUT.

### DETAILED DESCRIPTION OF THE DRAWINGS

In the drawings, like or similar elements are designated with identical reference numerals throughout the several views thereof, and the various elements depicted are not necessarily drawn to scale. FIG. 2 depicts one embodiment of a system 200 for generating a graphical representation of fault data of an MDUT 202 in accordance with the teachings of the present invention. The MDUT 202 is provided with address information 204 for addressing any memory location of the device, and is coupled to a test generator 206 by any conventional technique. In another arrangement, the test generator 206 itself may generate the necessary address space with respect to the MDUT. The MDUT 202 may include Electrically Erasable Programmable Read Only Memory (EEPROM or E²PROM), Erasable Programmable Read Only Memory (EPROM), Flash EPROM, Static Random Access Memory (SRAM), or Dynamic Random Access Memory (DRAM), for example.

The test generator 206 employs a verification technique and includes a test suite 208 that is comprised of a plurality of test vectors, labeled Test Vector 1 . . . Test Vector n. The success of any verification technique depends to a large extent on the nature and type of test vectors that are run on the MDUT 202. Accordingly, the test vectors for running bitmaps may be developed using a variety of verification techniques such as directed handwritten tests, focused random tests that target a specific function, random code generators, and libraries of worst-case tests for previous bugs, for example. For purposes of the present disclosure, a bitmap may be defined as a graphical representation of failing locations which matches or otherwise corresponds to the actual physical layout of an MDUT.

Typically, the test vectors exercise a portion of the MDUT 202 while one or more parameters of the MDUT 202 such as power supply voltage, temperature, or clock-speed, for example, are varied. In one embodiment, the test vectors exercise at least a portion of the MDUT 202 while incrementally varying a particular parameter. For example, a test vector may test one or more locations in the MDUT 202 as voltage is incrementally increased from 1.2 V to 1.3 V in steps of 0.02 V, for example. The test vectors may be verified by checking for an expected outcome in a memory location or a general register. Alternatively, test vectors may be verified by comparing the logical state of the entire MDUT 202 at the end of the test to some expected state. During the verification process or after the entire test suite has been executed, a bitmap debugging tool 210 monitors the failing locations of the MDUT 202 as a function of the parameter applied to the MDUT 202 and maintains a location-specific count of the number of times each address or location of the MDUT 202 failed. The bitmap debugging tool 210 may be any combination of hardware, firmware, and software that is coupled to the test generator and MDUT 202 in accordance with the teachings of the present invention. The bitmap debugging tool 210 maps the address and bit number information of the failing locations, i.e., fault data, outputted by the verification process to a graphical representation generation tool 212 that is operably associated with the bitmap debugging tool 210. The graphical representation generation tool 212 generates a single graphical representation or a consolidated plot of the fault data that integrates the fault data contained in multiple bitmap plots that would have been necessary in the conventional methodologies.

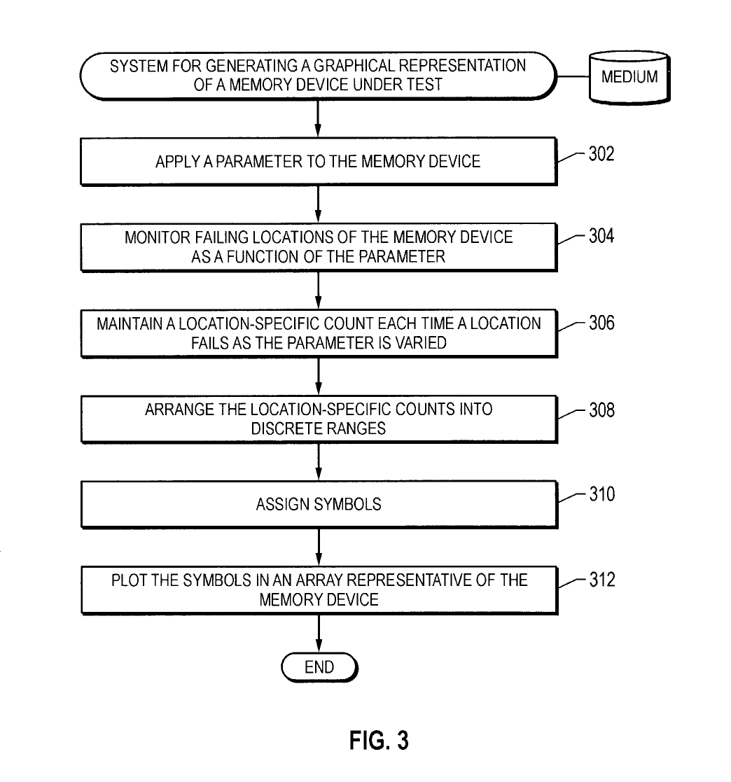

FIG. 3 depicts one embodiment of a method for generating a graphical representation of fault data of an MDUT. At block 302, a variable parameter is applied to the MDUT. At block 304, the failing locations of the MDUT are monitored as a function of the parameter. At block 306, a location-specific count is maintained each time a location fails as the parameter is varied. At block 308, the location-specific counts are arranged into discrete ranges. In one embodiment, the discrete ranges comprise ranges of equal size. At block 310, user-friendly symbols that can represent the entire range of location-specific failure counts are selected and assigned to the discrete ranges such that each discrete range is represented by a unique symbol. The symbols are indicative of the relative strengths or failure density of the discrete ranges. In one embodiment, the symbols may be comprised of colors selected from the visible spectrum and, moreover, the intensity and frequency of the colors can be coded to be indicative of the relative strengths of the discrete ranges. For example, the color RED may be selected to indicate a discrete range having high location-specific failure counts and the color BLUE may be selected to indicate a discrete range having low location-specific failure counts. Alternatively, the location-specific counts may not be arranged into discrete ranges and the individual symbols may be assigned to each location-specific count. At block 312, the encoded symbols are plotted in an array that is representative of the memory device in order to produce a single consolidated map that provides all the necessary information relating to the failure data, i.e., failure topologies, repetitive patterns, geometry-specific failure locations, etc. in a highly effective and user-friendly visual representation.

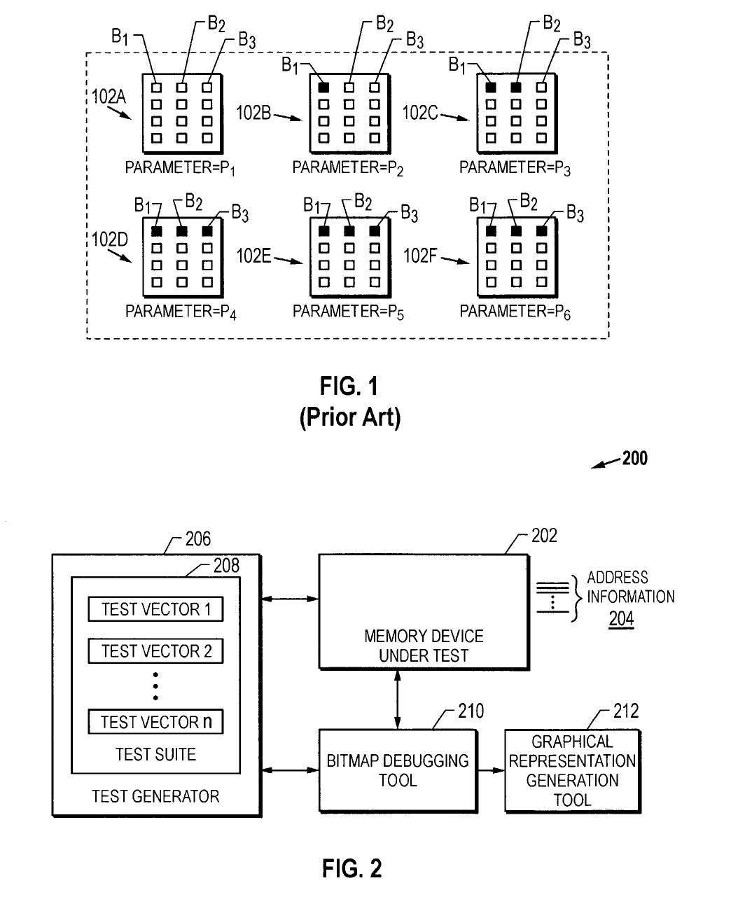

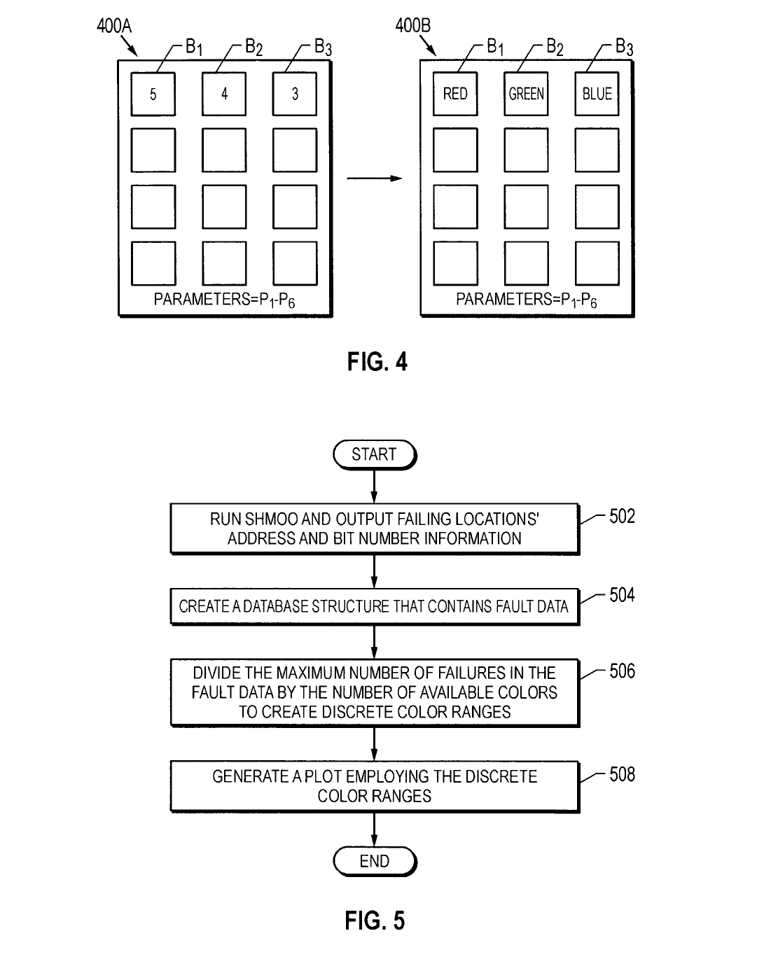

FIG. 4 depicts a graphical representation of a consolidated plot 400A and its encoded form 400B relating to the bitmap plots shown in FIG. 1. Consolidated plot 400A stores location-specific counts of the total number of times locations B₁-B₃ failed, respectively, as the parameter is varied from P1 to P₆. For example, location-specific count 5 indicates that the memory location B₁ failed five times. Similarly, the location-specific count 4 indicates that the memory location B₂ failed four times and the location-specific count 3 indicates that the memory location B₃ of the MDUT failed three times. Once testing is complete, a symbol indicative of the relative strength of the number of failures is assigned to each memory location B₁-B₃. In the illustrative embodiment, the symbols chosen are colors that are coded to be indicative of the number of failures a location experienced. For example, RED indicates more failures than GREEN which indicates more failures than BLUE. Accordingly, RED is assigned to memory location B₁ as that location failed the greatest number of times. Similarly, the color GREEN is assigned to memory location B₂ as that location failed an intermediate number of times. Finally, the color BLUE is assigned to memory location B₃ as that location failed the least number of times.

It should be appreciated that the “consolidation and encoding” concept illustrated hereinabove can also be applied to a situation where the location-specific failure count data is segregated into discrete ranges, each range being coded with a unique color. Moreover, where a large number of individual bitmap plots are involved (as the parametric values are varied over a considerable range), consolidation and classification of failure count data into discrete color-coded classes can result in a intuitive color gradient over a representative array which makes the observation of failure patterns easier and more efficient.

FIG. 5 depicts a particular embodiment of the method of FIG. 3 for generating the graphical representation of fault data of an MDUT. At block 502, a shmoo test is run over a range of parametric values and the failing locations' address and failure count information is outputted to a bitmap debugging tool. At block 504, a database structure is created that contains the outputted fault data. At block 506, the maximum number of failures present in the fault data is divided by the number of available colors to create discrete ranges ($STEP). At block 508, a color-coded graphical map or consolidated plot is generated that presents the physical locations corresponding to the failures in an intuitive symbolic scheme. When drawing a failing location, a determination is made whether the number of times that the location failed is between 0 and $STEP. If so, the “coolest” color of the selected color scheme is used to represent that location. Otherwise, if the failure count is between (i) ($STEP) and (i+1) ($STEP), where i=1, 2, . . . , n, an appropriate color that intuitively connotes the relative magnitude of the failure count will be assigned to the location.

Based on the foregoing Detailed Description, those skilled in the art should appreciate that the consolidated symbolic plots of the present invention, including the color-coded plots described herein, thereby provide a visual electrical verification scheme that is capable of representing the complete fault coverage data of a device's operating space and beyond. This provides for the detection of faults and fault patterns early in the design life cycle of the device, which ultimately ensures a reliable product with a longer life for the customer, and avoids costly in-production changes.

Although the invention has been described with reference to certain illustrations, it is to be understood that the forms of the invention shown and described are to be treated as exemplary embodiments only. Various changes, substitutions and modifications can be realized without departing from the spirit and scope of the invention as defined by the appended claims.

What is claimed is:

1. A method for generating a graphical representation of fault data of a memory device under test, comprising:
applying a parameter to said memory device;
monitoring failing locations of said memory device as a function of said parameter applied to said memory device;
maintaining a location-specific count each time one of said failing locations fails as said parameter is varied;
assigning a symbol to each of said failing locations based on its location-specific count; and
plotting said symbols in an array representative of said memory device under test.

2. The method as recited in claim 1, wherein the operation of applying a parameter to said memory device further comprises incrementally applying said parameter to said memory device.

3. The method as recited in claim 1, wherein the operation of assigning a symbol to each of said failing locations based on its location-specific count further comprises the operation of assigning a color to each of said failing locations based on its location-specific count.

4. A method for generating a graphical representation of fault data of a memory device under test, comprising:
applying a parameter to said memory device;
monitoring failing locations of said memory device as a function of said parameter applied to said memory device;
maintaining a location-specific count each time one of said failing locations fails as said parameter is varied;
arranging said location-specific counts of said failing locations into a plurality of discrete ranges;
assigning a symbol to each of said discrete ranges, wherein said symbols are indicative of relative strengths of said discrete ranges; and
plotting said symbols in an array representative of said memory device under test.

5. The method as recited in claim 4, wherein the operation of applying a parameter to said memory device further comprises incrementally applying said parameter to said memory device.

6. The method as recited in claim 4, wherein the operation of assigning a symbol to each of said discrete ranges further comprises the operation of assigning a color to each of said failing locations based on its location-specific count.

7. The method as recited in claim 6, wherein said color is indicative of the relative strength of said discrete ranges.

8. The method as recited in claim 4, wherein said discrete ranges are of equal size.

9. A computer-accessible medium having instructions for graphically representing fault data of a memory device under test, wherein said instructions, when executed on a computer system, perform the operations:
monitoring failing locations of said memory device as a function of a parameter applied to said memory device, wherein a location-specific count is maintained each time a location fails as said parameter is varied incrementally;
assigning a symbol to each of said failing locations based on its location-specific count; and
plotting said symbols in an array representative of said memory device under test.

10. The computer-accessible medium as recited in claim 9, further comprising instructions for arranging said location-specific counts of said failing locations into a plurality of discrete ranges.

11. The computer-accessible medium as recited in claim 10, wherein the instructions for assigning a symbol to each of said failing locations further comprise instructions for assigning said symbols to each of said discrete ranges, wherein said symbols are indicative of relative strengths of said discrete ranges.

12. The computer-accessible medium as recited in claim 9, wherein the instructions for assigning a symbol to each of said failing locations based on its location-specific count further comprise instructions for assigning a color to each of said failing locations based on its location-specific count.

13. A system for generating a graphical representation of fault data of a memory device under test, comprising:
a test vector generator for generating test vector code to be executed by said memory device, said test vector code operating to vary a parameter applied to at least a portion of said memory device's bit locations;
means for monitoring failing locations of said memory device as a function of said parameter applied to said memory device, wherein a location-specific count is maintained each time one of said bit locations fails as said parameter is varied;
means for assigning a symbol to each of said failing locations based on its location-specific count; and
means for plotting said symbols in an array representative of said memory device under test.

14. The system as recited in claim 13, wherein said parameter is selected from the group consisting of power supply voltage, temperature, and clock-speed.

15. The system as recited in claim 13, wherein said symbol comprises a color.

16. The system as recited in claim 13, wherein said test vector code is operable to incrementally vary said parameter.
